(19) United States
(12) Patent Application Publication
(10) Pub. No.: US 2025/0313955 A1
(43) Pub. Date: Oct. 9, 2025

(54) METHOD OF PROCESSING SUBSTRATE, METHOD OF MANUFACTURING SEMICONDUCTOR DEVICE, RECORDING MEDIUM, AND SUBSTRATE PROCESSING APPARATUS

(71) Applicant: KOKUSAI ELECTRIC CORPORATION, Tokyo (JP)

(72) Inventor: Yuki TAIRA, Toyama (JP)

(73) Assignee: KOKUSAI ELECTRIC CORPORATION, Tokyo (JP)

(21) Appl. No.: 19/245,920

(22) Filed: Jun. 23, 2025

Related U.S. Application Data
(63) Continuation of application No. PCT/JP2023/036233, filed on Oct. 4, 2023.

(30) Foreign Application Priority Data
Dec. 27, 2022 (JP) 2022-210106

(51) Int. Cl. C23C 16/52; C23C 16/44; C23C 16/455

(52) U.S. Cl. CPC C23C 16/52; C23C 16/4408; C23C 16/45523

(57) ABSTRACT

There is provided a technique that includes: (a) supplying a first processing gas from a first supplier into a process chamber in which the substrate is accommodated, while not supplying the first processing gas into the process chamber from a second supplier different from the first supplier; (b) supplying a second processing gas into the process chamber from each of the first supplier and the second supplier, and plasma-exciting the second processing gas inside the process chamber; and (c) supplying a third processing gas, which has a composition different from that of the second processing gas, into the process chamber from each of the first supplier and the second supplier, and plasma-exciting the third processing gas inside the process chamber.

### CROSS-REFERENCE TO RELATED APPLICATION

This application is a Bypass Continuation Application of PCT International Application No. PCT/JP2023/036233, filed on Oct. 4, 2023 and designating the United States, the international application being based upon and claiming the benefit of priority from Japanese Patent Application No. 2022-210106, filed on Dec. 27, 2022, the entire content of which is incorporated herein by reference.

### TECHNICAL FIELD

The present disclosure relates to a method of processing a substrate, a method of manufacturing a semiconductor device, a recording medium, and a substrate processing apparatus.

### BACKGROUND

As a process of manufacturing semiconductor devices, processing may be performed in which a plasma-excited processing gas is used to form a film on a substrate.

However, when performing substrate processing by using a plasma-excited processing gas, other gases in addition to the plasma-excited processing gas may be supplied and plasma-excited, such that the plasma-excited other gases may affect the substrate processing.

### SUMMARY

Embodiments of the present disclosure provides a technique capable of suppressing an influence on substrate processing caused by plasma excitation of gases other than a processing gas to be plasma-excited.

According to some embodiments of the present disclosure, there is provided a technique that includes: (a) supplying a first processing gas from a first supplier into a process chamber in which the substrate is accommodated, while not supplying the first processing gas into the process chamber from a second supplier different from the first supplier; (b) supplying a second processing gas into the process chamber from each of the first supplier and the second supplier, and plasma-exciting the second processing gas inside the process chamber; and (c) supplying a third processing gas, which has a composition different from that of the second processing gas, into the process chamber from each of the first supplier and the second supplier, and plasma-exciting the third processing gas inside the process chamber.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a substrate processing apparatus suitably used in embodiments of the present disclosure, in which a portion of the process furnace is shown in a vertical cross-section.

FIG. 2 is a schematic configuration diagram of the vertical process furnace of the substrate processing apparatus suitably used in embodiments of the present disclosure, in which a portion of the process furnace is shown in a cross-section taken along line A-A in FIG. 1.

FIG. 3A is a perspective view illustrating electrodes, suitably used in embodiments of the present disclosure, when fixed to an electrode fixture.

FIG. 3B is a diagram illustrating a positional relationship of a heater, electrode fixture, electrodes, protrusions for fixing the electrodes, and reaction tube, which are suitably used in embodiments of the present disclosure.

FIG. 4 is a schematic configuration diagram of a controller of the substrate processing apparatus suitably used in embodiments of the present disclosure, illustrating a control system of the controller in a block diagram.

FIG. 5 is a diagram illustrating an example of a processing sequence in embodiments of the present disclosure.

FIG. 6 is a schematic configuration diagram of the vertical process furnace of the substrate processing apparatus suitably used in a first modification of the present disclosure, illustrating the process furnace portion in a horizontal cross-sectional view.

FIG. 7 is a schematic configuration diagram of the vertical process furnace of the substrate processing apparatus suitably used in a second modification of the present disclosure, illustrating the process furnace portion in a horizontal cross-sectional view.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

### First Embodiment of Present Disclosure

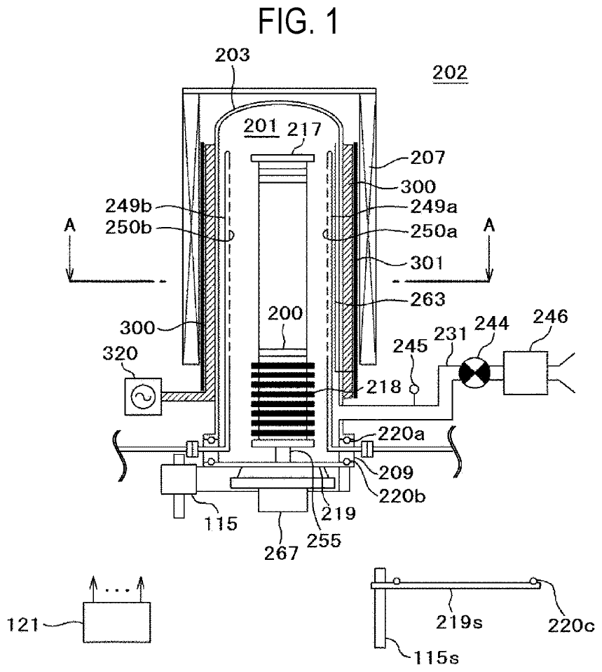

A first embodiment of the present disclosure will be described mainly with reference to FIGS. 1 to 5. In addition, drawings used in the following description are schematic, and dimensional relationships, ratios, and the like of various elements shown in the drawings may not match actual ones. Further, the dimensional relationships, ratios, and the like of various elements among plural drawings may not match one another.

### (Heating Device)

### (1) Configuration of Substrate Processing Apparatus

As illustrated in FIG. 1, a process furnace 202 includes a heater 207 serving as a temperature regulator (heating part). The heater 207 is formed in a cylindrical shape and is supported by a support plate so as to be vertically installed. The heater 207 also functions as an activator (a thermal exciter) configured to thermally activate (excite) a gas.

An electrode fixture 301, which will be described later, is disposed inside the heater 207, and an electrode 300 of a plasma generator, which will be described later, is disposed inside the electrode fixture 301. Furthermore, a reaction tube 203 is disposed to be concentric with the heater 207 inside the electrode 300. The reaction tube 203 is made of, for example, a heat resistant material such as quartz (SiO₂) or silicon carbide (SiC), and is formed in a cylindrical shape with its upper end closed and its lower end open. A manifold 209 is disposed to be concentric with the reaction tube 203 under the reaction tube 203. An upper end of the manifold 209 engages with the lower end of the reaction tube 203 via an O-ring 220a so as to support the reaction tube 203. A process container (reaction container) mainly includes the reaction tube 203 and the manifold 209. A process chamber 201 is formed in a hollow cylindrical region of the process container. The process chamber 201 is configured to be capable of accommodating a plurality of wafers 200 serving as substrates. In addition, the process container is not limited to the above configuration, and in some cases, the reaction tube 203 alone may be referred to as the process container.

### (Gas Supplier)

A first nozzle 249a, serving as a first supplier (first supply port), and a second nozzle 249b, serving as a second supplier (second supply port), are respectively installed inside the process chamber 201 so as to penetrate a sidewall of the manifold 209. The nozzles 249a and 249b are also referred to as first and second nozzles, respectively. The nozzles 249a and 249b are made of, for example, a heat resistant material such as quartz or SiC. Gas supply pipes 232a and 232b are respectively connected to the nozzles 249a and 249b. The process container is installed with two nozzles 249a and 249b and two gas supply pipes 232a and 232b, which enables supplying multiple types of gas into the process chamber 201.

The gas supply pipes 232a and 232b are installed respectively with valves 243a and 243b, which are opening/closing valves, and mass flow controllers (MFCs) 241a and 241b, which are flow-rate controllers (flow-rate control parts), sequentially from the upstream side of a gas flow. A gas supply pipe 232c is connected to the gas supply pipe 232a at the downstream side of the MFC 241a. Gas supply pipes 232d and 232e are connected respectively to the gas supply pipe 232b at the downstream side of the MFC 241b. The gas supply pipes 232c to 232e are installed respectively with valves 243c to 243e and MFCs 241c to 241e sequentially from the upstream side of a gas flow. A gas supply pipe 232f is connected to the gas supply pipe 232d at the upstream side of the valve 243d to interconnect the gas supply pipes 232a and 232d. The gas supply pipe 232f is connected to the gas supply pipe 232a at the downstream side of the MFC 241a. A gas supply pipe 232g is connected to the gas supply pipe 232e at the upstream side of the valve 243e to interconnect the gas supply pipes 232e and 232a). The gas supply pipe 232g is connected to the gas supply pipe 232a at the downstream side of the MFC 241a. The gas supply pipes 232f and 232g are installed respectively with valves 243f and 243g and MFCs 241f and 241g sequentially from the upstream side of a gas flow. The gas supply pipes 232a to 232g are made of, for example, a metal material such as stainless steel (SUS).

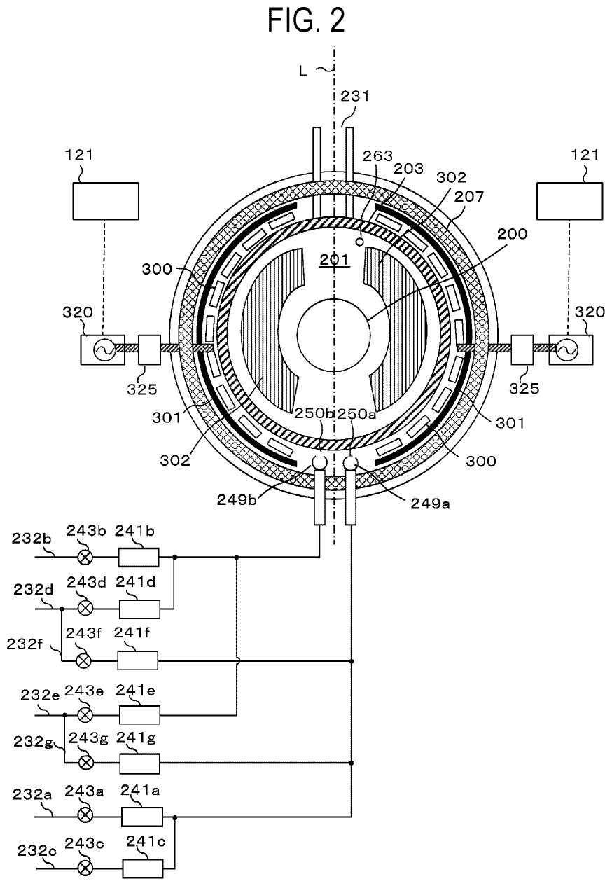

As illustrated in FIGS. 1 and 2, the nozzles 249a and 249b are installed in an annular space (in a plane view) between an inner wall of the reaction tube 203 and the wafers 200, so as to extend upward from a lower side to an upper side of the inner wall of the reaction tube 203, along the direction (vertical direction) in which the wafers 200 are stacked. In other words, the nozzles 249a and 249b are respectively installed on the lateral side of the end (peripheral edge) of each wafer 200 loaded into the process chamber 201 and oriented perpendicular to the surface (flat surface) of the wafer 200. Gas supply holes 250a and 250b configured to supply gas are respectively installed on the side surfaces of the nozzles 249a and 249b. The gas supply hole 250a is opened to face the center of the reaction tube 203, which enables a gas to be supplied toward the wafers 200. A plurality of gas supply holes 250a and 250b are installed from the lower side to the upper side of the reaction tube 203, respectively.

In this way, in the present embodiment, gases are delivered via the nozzles 249a and 249b disposed in an annular vertically elongated space, that is, a cylindrical space, in a plane view, which is defined by the inner sidewall of the reaction tube 203 and the ends (peripheral edges) of the plurality of wafers 200 arranged inside the reaction tube 203. Then, the gases are first ejected into the reaction tube 203 in the vicinity of the wafers 200 from the gas supply holes 250a and 250b, which are formed respectively in the nozzles 249a and 249b. Then, the main flow of gases inside the reaction tube 203 is directed parallel to the surface of the wafers 200, that is, in the horizontal direction. The gases that flow on the surface of the wafers 200, that is, the reacted residual gases, then flow toward an exhaust port, that is, toward an exhaust pipe 231, which will be described later.

A first process gas is supplied from the gas supply pipe 232a into the process chamber 201 via the valve 243a, the MFC 241a, and the nozzle 249a.

An inert gas is supplied from the gas supply pipes 232b and 232c into the process chamber 201 via the valves 243b and 243c, the MFCs 241b and 241c, the gas supply pipes 232b and 232a, and the nozzles 249b and 249a. The inert gas acts as a purge gas, a carrier gas, or a dilution gas, or the like.

A second process gas is supplied from the gas supply pipe 232d into the process chamber 201 via the valve 243d, the MFC 241d, and the nozzle 249b.

A third process gas is supplied from the gas supply pipe 232e into the process chamber 201 via the valve 243e, the MFC 241e, and the nozzle 249b.

The second process gas is supplied from the gas supply pipe 232f into the process chamber 201 via the valve 243f, the MFC 241f, and the nozzle 249a.

The third process gas is supplied from the gas supply pipe 232g into the process chamber 201 via the valve 243g, the MFC 241g, and the nozzle 249a.

A precursor gas supply system, serving as a first process gas supply system, mainly includes the gas supply pipe 232a, the valve 243a, and the MFC 241a. A reactant gas supply system, serving as a second process gas supply system, mainly includes the gas supply pipes 232d and 232f, the valves 243d and 243f, and the MFCs 241d and 241f. A treatment gas supply system, serving as a third process gas supply system, mainly includes the gas supply pipes 232e and 232g, the valves 243e and 243g, and the MFCs 241e and 241g. An inert gas supply system mainly includes the gas supply pipes 232b and 232c, the valves 243b and 243c, and the MFCs 241b and 241c. The precursor gas supply system, the reactant gas supply system, the treatment gas supply system, and the inert gas supply system are simply referred to as a gas supply system (gas supplier).

### (Substrate Support)

As illustrated in FIG. 1, a boat 217 serving as a substrate support is configured to support a plurality of wafers 200, for example, 25 to 200 wafers, in such a state that the wafers 200 are arranged to be spaced apart from each other in a horizontal posture and in multiple stages along a vertical direction with the centers of the wafers 200 aligned with one another. The boat 217 is made of, for example, a heat resistant material such as quartz or SiC. Heat insulating plates 218 made of, for example, a heat resistant material such as quartz or SiC are installed below the boat 217 in multiple stages.

### (Plasma Generator)

Next, a plasma generator will be described with reference to FIGS. 1 to 3B.

The electrode 300 for plasma generation is installed outside the reaction tube 203, that is, outside (at the outer periphery of) the process container (process chamber 201). By applying electric power to the electrode 300, it becomes possible to excite a gas by generating plasma from the gas, that is, to excite the gas into a plasma state, inside the reaction tube 203, that is, inside the process container. Hereinafter, the excitation of a gas into a plasma state may also be simply referred to as plasma-excitation. The electrode 300, when radio frequency power (RF power) is applied, is configured to generate capacitively-coupled plasma (abbreviation: CCP) inside the reaction tube 203, that is, inside the process container.

Specifically, as illustrated in FIG. 2, the electrode 300 and the electrode fixture 301 configured to fix the electrode 300 are arranged between the heater 207 and the reaction tube 203. The electrode fixture 301 is disposed inside the heater 207, the electrode 300 is disposed inside the electrode fixture 301, and the reaction tube 203 is disposed inside the electrode 300.

Further, as illustrated in FIGS. 1 and 2, the electrode 300 and the electrode fixture 301 are installed respectively to extend in the arrangement direction of the wafers 200 from a lower side to an upper side of an outer wall of the reaction tube 203 in an annular space (in a plane view) between an inner wall of the heater 207 and the outer wall of the reaction tube 203. The electrode 300 is installed in parallel to the nozzles 249a and 249b. The electrode 300 and the electrode fixture 301 are disposed to be arranged concentrically with the reaction tube 203 and the heater 207 in a plane view, and in a non-contact manner with the heater 207.

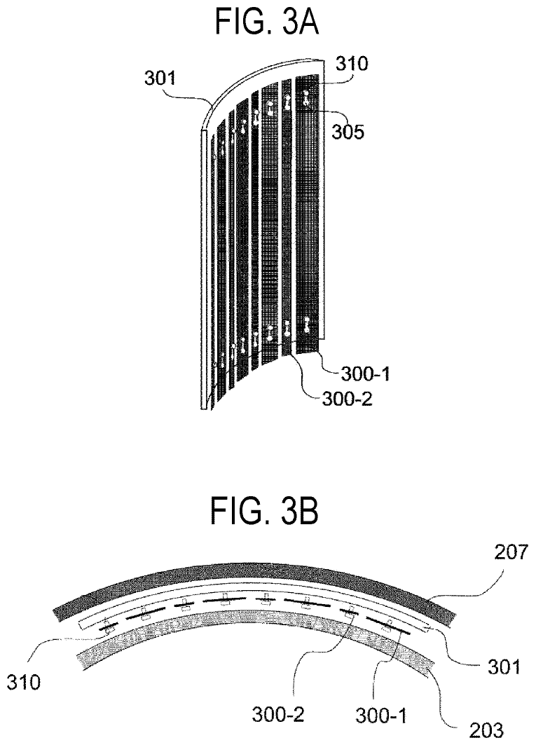

As illustrated in FIG. 2, a plurality of electrodes 300 are installed, and these electrodes 300 are fixed to an inner wall of the electrode fixture 301. More specifically, a protrusion (hook) 310 on which the electrode 300 may be hooked is installed at the inner wall surface of the electrode fixture 301, and an opening 305, which is a through-hole through which the protrusion 310 may be inserted, is installed at the electrode 300. The electrode 300 may be fixed to the electrode fixture 301 by hooking the electrode 300 onto the protrusion 310 installed at the inner wall surface of the electrode fixture 301 through the opening 305. In addition, FIG. 2 illustrates an example including two configurations (units) formed by nine electrodes 300 being fixed to one electrode fixture 301. FIGS. 3A and 3B illustrate an example including one configuration (unit) formed by eight electrodes 300-1 and 300-2 being fixed to one electrode fixture 301.

As illustrated in FIGS. 2 and 3A, the electrodes 300 include a first electrode 300-1 and a second electrode 300-2. The first electrode 300-1 is connected to a radio frequency power supply (RF power supply) 320 via a matcher 325, and an arbitrary potential is applied to the first electrode 300-1. The second electrode 300-2 is grounded to earth serves as a reference potential (0 V). The first electrode 300-1 and the second electrode 300-2 are each configured as a plate-like member of a rectangular shape when viewed from the front. FIGS. 2, 3A and 3B illustrate examples in which a plurality of first electrodes 300-1 and a plurality of second electrodes 300-2 are each installed. In the example of FIGS. 3A and 3B, four first electrodes 300-1 and four second electrodes 300-2 are installed. By applying RF power between the first electrode 300-1 and the second electrode 300-2 from the RF power supply 320 via the matcher 325, plasma is generated in a region between the first electrode 300-1 and the second electrode 300-2. This region is also referred to as a plasma generation region. As illustrated in FIG. 2, the electrodes 300 are arranged to extend in the direction in which the plurality of wafers 200 are stacked, and are arranged in an arc shape in a plane view. Further, the electrodes 300 are fixed to the inner wall surface of the electrode fixture 301, which is arranged between the reaction tube 203 and the heater 207, in a substantially arc shape in a plane view along the outer wall of the reaction tube 203. Further, as described above, the electrodes 300 are installed in parallel to the nozzles 249a and 249b.

Here, the electrode fixture 301 and the electrodes 300 (the first electrode 300-1 and the second electrodes 300-2) may also be referred to as an electrode unit. FIG. 2 illustrates an example in which two electrode units are arranged to oppose (face) each other with the center of the wafers 200 (reaction tube 203) interposed therebetween, avoiding the nozzles 249a and 249b and the exhaust pipe 231.

Radio frequency power within the range of, for example, 25 MHz to 35 MHz is input from the RF power supply 320 to the electrodes 300 via the matcher 325, thereby generating plasma 302 inside the reaction tube 203. Gas activated by the generated plasma is supplied from the periphery of the wafers 200 to the surface of the wafers 200. The activated gas becomes a gas containing an active species used in substrate processing.

The electrodes 300, that is, the first electrode 300-1 and the second electrode 300-2, mainly constitutes a plasma generator (plasma exciter (exciter) or plasma activator) that excites (activates) a gas into a plasma state. The electrode fixture 301, the matcher 325, and the RF power supply 320 may also be considered as included in the plasma generator.

### (Exhauster)

As illustrated in FIG. 1, the reaction tube 203 is installed with the exhaust pipe 231 configured to exhaust an internal atmosphere of the process chamber 201. The exhaust pipe 231 is connected to a vacuum pump 246, serving as a vacuum exhauster, via a pressure sensor 245, serving as a pressure detector (pressure detection part) configured to detect the internal pressure of the process chamber 201, and an auto pressure controller (APC) valve 244, serving as an exhaust valve (pressure regulator). The APC valve 244 is configured to perform or stop a vacuum exhaust operation in the process chamber 201 by opening or closing the valve while the vacuum pump 246 is actuated. The APC valve 244 is also configured to regulate the internal pressure of the process chamber 201 by adjusting a degree of valve opening based on pressure information detected by the pressure sensor 245 while the vacuum pump 246 is actuated. An exhaust system mainly includes the exhaust pipe 231, the APC valve 244, and the pressure sensor 245. The vacuum pump 246 may also be considered as included in the exhaust system.

### (Peripheral Device)

A seal cap 219, which serves as a furnace opening lid configured to be capable of hermetically sealing a lower end opening of the manifold 209, is installed under the manifold 209. The seal cap 219 is configured to make contact with the lower end of the manifold 209 via an O-ring 220b from the vertical lower side.

A rotator 267 configured to rotate the boat 217 is provided at a side of the seal cap 219 which is opposite to the process chamber 201. A rotary shaft 255 of the rotator 267 is connected to the boat 217 through the seal cap 219. The rotator 267 is configured to rotate the wafers 200 by rotating the boat 217. A boat elevator 115, which serves as an elevator provided vertically outside the reaction tube 203, is configured to raise or lower the seal cap 219, thereby enabling the loading or unloading of the boat 217 into or out of the process chamber 201.

The boat elevator 115 is configured as a transporter (transport equipment) which transports the boat 217, that is, the wafers 200, into or out of the process chamber 201. Further, a shutter 219s, which is capable of hermetically sealing the lower end opening of the manifold 209 via an O-ring 220c while the seal cap 219 is being lowered, is installed under the manifold 209. The opening/closing operation of the shutter 219s is controlled by a shutter opening/closing mechanism 115s.

A temperature sensor 263 serving as a temperature detector is provided inside the reaction tube 203. Based on temperature information detected by the temperature 263, a state of supplying electric power to the heater 207 is regulated such that the internal temperature of the process chamber 201 falls within a desired temperature distribution. The temperature sensor 263 is installed along the inner wall of the reaction tube 203, similar to the nozzles 249a and 249b.

### (Control Device)

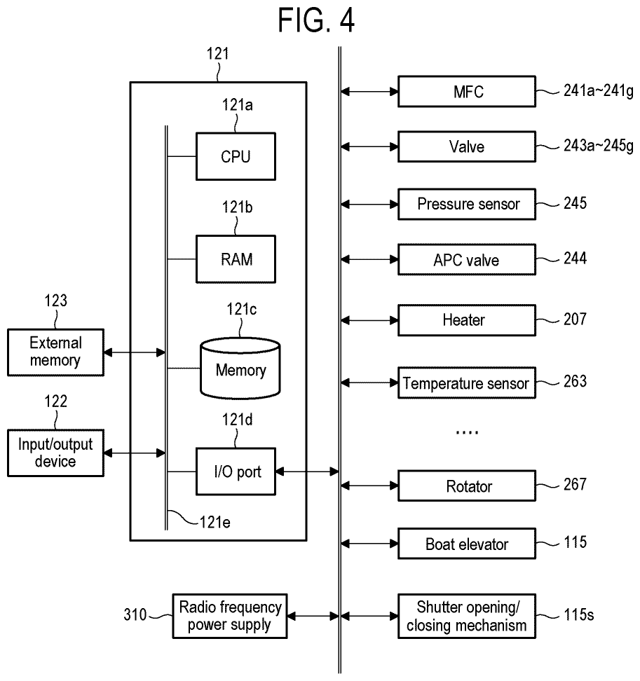

Next, a control device will be described with reference to FIG. 4. As illustrated in FIG. 4, a controller 121, which is a control part (control device), is configured as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 including, for example, a touch panel or the like, is connected to the controller 121.

The memory 121c includes, for example, a flash memory, a hard disk drive (HDD), and a solid state drive (SSD), or the like. A control program that controls operations of a substrate processing apparatus, a process recipe in which sequences and conditions of film formation processes to be described later are written, etc. are readably stored in the memory 121c. The process recipe functions as a program that combines the respective sequences of various types of processes (film formation process), which will be described later. The program causes, by the controller 121, the substrate processing apparatus to execute each sequence in the recipe to obtain an expected result. Hereinafter, the process recipe and the control program may be generally and simply referred to as a “program.” Further, the process recipe may be simply referred to as a “recipe.” When the term “program” is used herein, it may indicate a case of including the recipe, a case of including the control program, or a case of including both the recipe and the control program. The RAM 121b is configured as a memory area (work area) in which programs, data, or others read by the CPU 121a are temporarily stored.

The I/O port 121d is connected to the above-described MFCs 241a to 241d, valves 243a to 243d, pressure sensor 245, APC valve 244, vacuum pump 246, heater 207, temperature sensor 263, rotator 267, boat elevator 115, shutter opening/closing mechanism 115s, and RF power supply 320, and so on.

The CPU 121a is configured to read and execute the control program from the memory 121c and to read the recipe from the memory 121c, according to an input of an operation command from the input/output device 122, etc. The CPU 121a is configured to be capable of controlling the rotator 267, flow rate regulating operations of various gases by the MFCs 241a to 241d, opening/closing operations of the valves 243a to 243d, an opening/closing operation of the APC valve 244, a pressure regulating operation by the APC valve 244 based on the pressure sensor 245, actuating and stopping operations of the vacuum pump 246, a temperature regulating operation by the heater 207 based on the temperature sensor 263, forward/reverse rotation, rotational angle, and rotational speed regulating operations of the boat 217 by the rotator 267, an operation of moving the boat 217 up or down by the boat elevator 115, an opening/closing operation of the shutter 219s by the shutter opening/closing mechanism 115s, the supply of electric power from the RF power supply 320, and so on, according to contents of the read recipe.

The controller 121 may be configured by installing, on the computer, the above-described program stored in an external memory (e.g., a magnetic disk such as a hard disk, an optical disk such as a CD, a magneto-optical disk such as a MO, and a semiconductor memory such as a USB memory) 123. The memory 121c or the external memory 123 is configured as a computer-readable recording medium. Hereinafter, the memory 121c and the external memory 123 may be generally and simply referred to as a “recording medium.” When the term “recording medium” is used herein, it may indicate a case of including the memory 121c, a case of including the external memory 123, or a case of including both the memory 121c and the external memory 123. In addition, the program may be provided to the computer by using a communication means or unit such as the Internet or a dedicated line, instead of using the external memory 123.

### (2) Substrate Processing Process

As a process of manufacturing a semiconductor device by using the above-described substrate processing apparatus, an example of a processing sequence of forming a film on a wafer 200 serving as a substrate, that is, a film-forming sequence, will be described. In the following descriptions, operations of respective components constituting the substrate processing apparatus are controlled by the controller 121.

The film formation sequence according to the present embodiment forms a film on the wafer 200 by performing a process including:
step a of supplying a first processing gas into the process chamber, in which the wafer 200 is accommodated, from a first nozzle serving as a first supplier (first supply port), while not supplying the first processing gas into the process chamber from a second nozzle serving as a second supplier (second supply port) that is different from the first nozzle;
step b of supplying a second processing gas into the process chamber from each of the first and second nozzles, and plasma-exciting the second processing gas inside the process chamber; and
step c of supplying a third processing gas, which has a composition different from that of the second processing gas, into the process chamber from each of the first and second nozzles, and plasma-exciting the third processing gas inside the process chamber.

In the present embodiment, the case where the first processing gas is not plasma-excited in step a will be described.

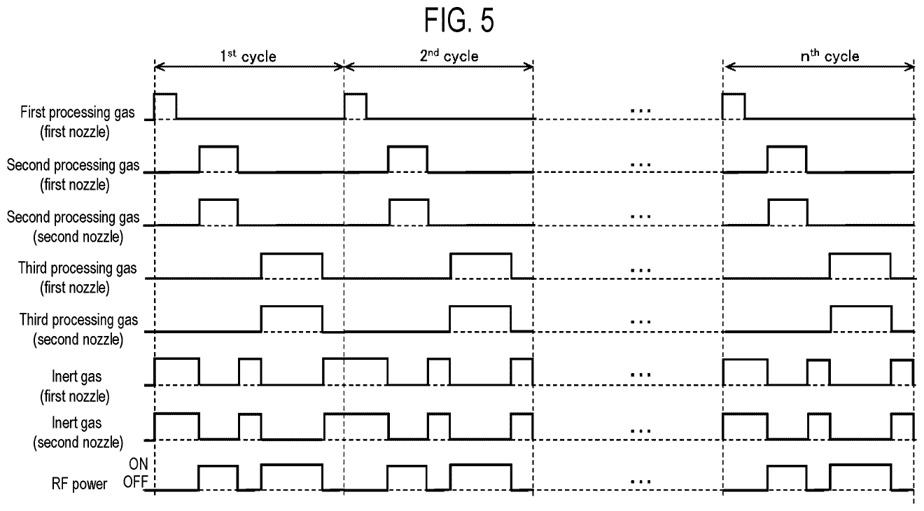

As illustrated in FIG. 5, in the processing sequence of the present embodiment, by performing a cycle including steps a, b, and c performed non-simultaneously a predetermined number of times (n times, where n is an integer of 1 or more), a film is formed on the wafer 200.

In the present disclosure, for the sake of convenience, the above-described processing sequence (gas supply sequence) may also be denoted as follows. The same notation is also used in the description of other embodiments and modifications to be described later.

(First processing gas→Plasma-excited second processing gas→Plasma-excited third processing gas)×n

The processing sequence illustrated in FIG. 5 illustrates an example in which a cycle of steps a, b, and c in this order is performed a plurality of times (n times). In this case, n is an integer of 2 or more. FIG. 5 further illustrates an example in which the interior of the process container is purged with an inert gas in a non-plasma atmosphere, after performing step a and before performing step b. In addition, the interior of the process container may be purged with an inert gas in a non-plasma atmosphere, after performing step b and before performing step c. Further, when performing the cycle is a plurality of times, the interior of the process container may be purged with an inert gas in a non-plasma atmosphere, after performing step c and before performing step a. This enables the suppression of mixing of different gases in a plasma state inside the process container, unintended reactions resulting from the mixing, generation of particles, and the like. These processing sequences may be shown as follows. In addition, in the following, “P” denotes a purge performed in a non-plasma atmosphere. In the present embodiment, as an example, a case in which the interior of the process container is purged with an inert gas in a non-plasma atmosphere in any of the following cases: after performing step a and before performing step b, after performing step b and before performing step c, and after performing step c and before performing step a, will be described.

(First processing gas→P→Plasma-excited second processing gas→Plasma-excited third processing gas)×n

(First processing gas→P→Plasma-excited second processing gas→P→Plasma-excited third processing gas)×n

(First processing gas→P→Plasma-excited second processing gas→Plasma-excited third processing gas→P)×n

(First processing gas→P→Plasma-excited second processing gas→P→Plasma excited-third processing gas→P)×n

In addition, an example in which the film to be formed is a nitride film will be described below. Here, the term “nitride film” includes a silicon nitride film (SiN film) and a nitride film containing carbon (C), oxygen (O), boron (B), and the like. That is, the nitride film includes a silicon nitride (SiN film), silicon carbonitride (SiCN film), silicon oxynitride (SiON film), silicon oxycarbonitride (SiOCN film), silicon borocarbonitride film (SiBCN film), silicon boronitride (SiBN film), silicon boronoxycarbonitride (SiBOCN film), or silicon boronoxynitride (SiBON film), and the like. An example in which a SiN film is formed as the nitride film will be described below.

The term “wafer” used in the present disclosure may refer to “a wafer itself” or “a stacked body of a wafer and certain layers or films formed on a surface of the wafer.” The phrase “a surface of a wafer” used in the present disclosure may refer to “a surface of a wafer itself” or “a surface of a certain layer or the like formed on a wafer.” The expression “a certain layer is formed on a wafer” used in the present disclosure may mean that “a certain layer is formed directly on a surface of a wafer itself” or that “a certain layer is formed directly on a layer formed on a wafer.” The term “substrate” used in the present disclosure may be synonymous with the term “wafer.”

### (Wafer Charging)

The boat 217 is charged with a plurality of wafers 200 (wafer charging). Thereafter, the shutter 219s is moved by the shutter opening/closing mechanism 115s to open the lower end opening of the manifold 209. The wafers 200 include product wafers and dummy wafers.

### (Boat Loading)

Thereafter, as illustrated in FIG. 1, the boat 217 charged with the plurality of wafers 200 is lifted up by the boat elevator 115 to be loaded into the process chamber 201 (boat loading). In this state, the seal cap 219 seals the lower end of the manifold 209.

### (Pressure Regulation and Temperature Regulation)

After the boat loading is completed, the interior of the process chamber 201, that is, a space where the wafers 200 are placed, is vacuum-exhausted (decompression-exhausted) by the vacuum pump 246 to reach a desired pressure (state of vacuum). At this time, the internal pressure of the process chamber 201 is measured by the pressure sensor 245, and the APC valve 244 is feedback-controlled based on the measured pressure information (pressure regulation). Further, the wafers 200 in the process chamber 201 are heated by the heater 207 to reach a desired processing temperature. At this time, a state of supplying electric power to the heater 207 is feedback-controlled based on the temperature information detected by the temperature sensor 263 such that a temperature distribution inside the process chamber 201 becomes a desired temperature distribution (temperature regulation). Further, the rotation of the wafers 200 by the rotator 267 is initiated. The exhaust of the interior of the process chamber 201 and the heating and rotation of the wafers 200 are continuously performed at least until the processing on the wafers 200 is complete.

### (Film Formation Processing)

Thereafter, the following steps a, b, and c are performed in sequence.

[Step a]

In step a, a precursor gas serving as a first processing gas is supplied to the wafers 200 in the process chamber 201.

Specifically, the valve 243a is opened to allow the first processing gas to flow through the gas supply pipe 232a. A flow rate of the first processing gas is regulated by the MFC 241a, and the first processing gas is supplied into the process chamber 201 via the nozzle 249a and exhausted from the exhaust port 231a. At this time, the first processing gas is supplied to the wafers 200 from the lateral side of the wafers 200 (supply of first processing gas). At this time, the valves 243b and 243c are opened to allow an inert gas to be supplied into the process chamber 201 via the nozzles 249a and 249b, respectively. In this step, the inert gas supplied via the nozzle 249a acts, for example, as a carrier gas and/or a dilution gas for the first processing gas. Further, the inert gas supplied via the nozzle 249b may be supplied to prevent the gas from entering (backflow) the nozzle 249b, and may also be supplied for other purposes, such as regulating a gas flow inside the process chamber 201.

Processing conditions in this step are exemplified as follows:
Processing temperature: 250 to 550 degrees C., specifically 400 to 500 degrees C.;
Processing pressure: 100 to 4,000 Pa, specifically 100 to 1,000 Pa;
Supply flow rate of first processing gas: 0.1 to 3 slm;
Supply time of first processing gas: 1 to 100 seconds, specifically 1 to 30 seconds; and
Supply flow rate of inert gas (for gas supply pipe): 0 to 10 slm.

In the present disclosure, notation of a numerical range such as “250 to 550 degrees C.” means that a lower limit value and an upper limit value are included in that range. Therefore, for example, “250 to 550 degrees C.” means “250 degrees C. or higher and 500 degrees C. or lower.” The same applies to other numerical ranges. In the present disclosure, the processing temperature means the temperature of the wafers 200 or the internal temperature of the process chamber 201, and the processing pressure means the internal pressure of the process chamber 201. Further, when the flow rate of gas supply is 0 slm, it means a case in which no gas is supplied. The same applies to the following description.

By supplying, for example, a chlorosilane-based gas as the first processing gas (precursor gas) to the wafers 200 under the above-described condition, a Si-containing layer containing Cl is formed on the outermost surface of the wafers 200 as a base. The Si-containing layer containing Cl is formed on the outermost surface of the wafers 200 by physical adsorption or chemical adsorption of molecules of the chlorosilane-based gas, physical adsorption or chemical adsorption of molecules of a substance obtained by partially decomposing the chlorosilane-based gas, deposition of Si due to thermal decomposition of the chlorosilane-based gas, or the like. In the present disclosure, the Si-containing layer containing Cl is also simply referred to as a Si-containing layer.

After the Si-containing layer is formed, the valve 243a is closed to stop the supply of the first processing gas into the process chamber 201. Then, the interior of the process chamber 201 is vacuum-exhausted to remove remaining gases and the like in the process chamber 201 from the process chamber 201 (purging). At this time, the valves 243b and 243c are left open to allow an inert gas to be supplied into the process chamber 201. At this time, the inert gas acts as a purge gas.

As the first processing gas, for example, a silane-based gas containing silicon (Si), which is a first predetermined element serving as a main element constituting a film to be formed on the wafers 200, may be used. As the silane-based gas, for example, a gas containing Si and a halogen element, that is, a halosilane-based gas may be used. The halogen includes chlorine (Cl), fluorine (F), bromine (Br), iodine (I), and the like. As the halosilane-based gas, for example, the above-described chlorosilane-based gas containing Si and Cl may be used.

Examples of the first processing gas may include chlorosilane-based gases such as a monochlorosilane (SiH₃Cl) gas, a dichlorosilane (SiH₂Cl₂) gas, a trichlorosilane (SiHCl)₃) gas, a tetrachlorosilane (SiCl₄) gas, a hexachlorodisilane (Si₂Cl₆) gas, and an octachlorotrisilane (Si₃Cl₈) gas. One or more of these gases may be used as the first processing gas.

In addition to the chlorosilane-based gases, examples of the first processing gas may also include fluorosilane-based gases such as a tetrafluorosilane (SiF₄) gas and a difluorosilane (SiH₂F₂) gas, bromosilane-based gases such as a tetrabromosilane (SiBr₄) gas and a dibromosilane (SiH₂Br₂) gas, and iodosilane-based gases such as a tetraiodosilane (SiI₄) gas and a diiodosilane (SiH₂I₂) gas. One or more of these gases may be used as the first processing gas.

In addition to the above, examples of the first processing gas may also include gases containing Si and an amino group, that is, aminosilane-based gases, such as a tetrakis(dimethylamino)silane (Si[N(CH₃)₂]₄) gas, a tris(dimethylamino)silane (Si[N(CH₃)₂]₃H) gas, a bis(diethylamino)silane (Si[N(C₂H₅)₂]₂H₂) gas, a bis(tert-butylamino)silane (SiH₂[NH(C₄H₉)]₂) gas, and a (diisopropylamino)silane (SiH₃[N(C₃H₇)₂]) gas. One or more of these gases may be used as the first processing gas.

Examples of the inert gas may include a nitrogen (N₂) gas, and rare gases such as an argon (Ar) gas, a helium (He) gas, a neon (Ne) gas, or a xenon (Xe) gas and the like. One or more of these gases may be used as the inert gas. The same applies to each step to be described later. In addition, the term “inert gas” used in the present disclosure may include a gas that may be activated by applying activation energy, such as by excitation into a plasma state.

The inert gas used in this step is a gas different from the above-described first processing gas. Further, the inert gas used in this step is also different from any of a second processing gas and a third processing gas described later. However, in another embodiment, the same gas as either the second processing gas or the third processing gas may be used as the inert gas in this step. By using the inert gas that is the same as either the second processing gas or the third processing gas in this step, it may be possible to simplify the configuration of the gas supply system.

[Step b]

After the completion of step a, a reaction gas, serving as a second processing gas, is excited to a plasma state and supplied to the wafers 200 inside the process chamber 201, that is, the Si-containing layer formed on the wafers 200.

Specifically, the valves 243d and 243f are opened to allow the second processing gas to flow through the gas supply pipes 232d and 232f. A flow rate of the second processing gas is regulated by the MFCs 241d and 241f, and is supplied into the process chamber 201 via the nozzles 249b and 249a (supply of the second processing gas). At this time, radio frequency power is supplied (applied) from the RF power supply 320 to the electrodes 300. The second processing gas supplied into the process chamber 201 is excited to a plasma state in the interior of the process chamber 201, and is then supplied as an active species to the wafers 200 and exhausted from the exhaust pipe 231. Further, at this time, the valves 243b and 243c are closed to stop the supply of the inert gas into the process chamber 201. That is, in this step, the second processing gas alone is supplied into the process chamber 201 via the nozzles 249a and 249b, and the supply of any gas other than the second processing gas into the process chamber 201 is not performed.

Processing conditions in this step are exemplified as follows:
Processing temperature: 250 to 550 degrees C., specifically 400 to 500 degrees C.;
Processing pressure: 2 to 100 Pa, specifically 20 to 70 Pa;
Supply flow rate of second processing gas (for each gas supply pipe): 0.1 to 10 slm;
Supply time of second processing gas: 10 to 600 seconds, specifically 1 to 50 seconds;
RF Power: 100 to 1,000 W; and
RF frequency: 25 MHz to 35 MHz.

In the present embodiment, as an example, the flow rates of the second processing gas supplied from each of the nozzles 249a and 249b are the same. This facilitates a more uniform concentration distribution of the second processing gas inside the process chamber 201. In addition, in the present disclosure, the phrase “the flow rates of the gas supplied from the nozzles 249a and 249b are same” includes a case in which the flow rates are exactly the same and a case in which the difference between the flow rate of the gas supplied from the nozzle 249a and the flow rate of the gas supplied from the nozzle 249b is within +5%.

By exciting a nitriding gas (nitriding agent) such as a nitrogen (N)- and hydrogen (H)-containing gas into a plasma state and supplying it to the wafers 200 as the second processing gas under the above-described condition, at least a portion of the Si-containing layer formed on the wafers 200 is nitrided (modified). As a result, a silicon nitride layer (SiN layer) is formed as a layer containing Si and N on the outermost surface of the wafers 200 serving as a base. When forming the SiN layer, impurities such as Cl contained in the Si-containing layer form a gaseous substance containing at least Cl in the process of a modification reaction of the Si-containing layer by the N- and H-containing gas, and are discharged from the process chamber 201. Thus, the SiN layer becomes a layer containing fewer impurities such as Cl than the Si-containing layer formed in step a.

Here, when a gas other than the second processing gas is supplied from at least one selected from the group of the nozzles 249a and 249b, the other gas is also plasma-excited inside the process chamber 201 along with the second processing gas. The plasma-excited other gas may act on the surface of the wafers 200 (the Si-containing layer in the present embodiment). Further, the plasma-excited other gas may act on the second processing gas, for example, by promoting the activation of the second processing gas. Accordingly, the plasma-excited other gas may cause an unintended effect on the processing of the wafers 200, which would not occur in a case in which the second processing gas alone is supplied. This also applies to the case in which the other gas is the above-described inert gas. In this step, the second processing gas alone is supplied into the process chamber 201 via the nozzles 249a and 249b, and no gas other than the second processing gas is supplied into the process chamber 201. This suppresses influences of other gases, such as deteriorations of in-plane uniformity of film quality and film thickness across the surface of the wafers 200, inter-wafer uniformity, and the like.

After the SiN layer is formed, the valves 243d and 243f are closed to stop the supply of the second processing gas into the process chamber 201. Further, the supply of RF power to the electrodes 300 is stopped. Then, according to the same processing procedure as the purging in step a, the valves 243b and 243c are opened to allow an inert gas to be supplied into the process chamber 201 via the nozzles 249a and 249b, so that the interior of the process chamber 201 is vacuum-exhausted to remove remaining gases and the like in the process chamber 201 (purging).

As the second processing gas, for example, a nitriding gas (nitriding agent) may be used. An example of the nitriding gas may include the above-described N- and H-containing gas. The N- and H-containing gas is both a N-containing gas and a H-containing gas. Specifically, the N- and H-containing gas may contain a N—H bond.

As the N- and H-containing gas, for example, hydrogen nitride-based gases, such as an ammonia (NH₃) gas, a diazene (N₂H₂) gas, a hydrazine (N₂H₄) gas, or a N₃H₈ gas, may be used. Further, for example, a mixed gas of a N-containing gas and a H-containing gas, such as a mixed gas of N₂ gas and hydrogen (H₂) gas, may also be used. One or more of these gases may be used as the second processing gas. Further, as the second processing gas, for example, a N₂ gas serving as a nitriding gas may be used.

In addition to these gases, for example, a nitrogen (N)-, carbon (C)-, and hydrogen (H)-containing gas may also be used as the second processing gas. As the N-, C-, and H-containing gas, for example, an amine-based gas or an organic hydrazine-based gas may be used. The N-, C-, and H-containing gas is a N-containing gas, a C-containing gas, and a H-containing gas, and is also a N- and C-containing gas.

As the second processing gas, for example, ethylamine-based gases such as a monoethylamine (C₂H₅NH₂) gas, a diethylamine ((C₂H₅)₂NH) gas, and a triethylamine ((C₂H₅)₃N) gas, methylamine-based gases such as a monomethylamine (CH₃NH₂) gas, a dimethylamine ((CH₃)₂NH) gas, and a trimethylamine ((CH₃)₃N) gas, organic hydrazine-based gases such as a monomethylhydrazine ((CH₃) HN₂H₂) gas, a dimethylhydrazine ((CH₃)₂N₂H₂) gas, and a trimethylhydrazine ((CH₃)₂N₂(CH₃)H) gas and the like may be used as the second processing gas. One or more of these gases may be used as the N- and H-containing gas.

Further, even a gas that is inactive in a non-plasma state, such as the above-described inert gas, may act as an active species on the wafers 200 by being excited to a plasma state. That is, at least one selected from the group of a N₂ gas and a noble gas, or a mixed gas of at least one selected from the group of a N₂ gas and a noble gas and another gas may be used as the second processing gas. Even in such cases, in this step, no gas other than the gas used as the second processing gas is supplied into the process chamber 201 via the nozzles 249a and 249b.

[Step c]

After the completion of step b, a treatment gas, serving as a third processing gas, which has a composition different from that of the second processing gas, is excited to a plasma state and supplied to the wafers 200 inside the process chamber 201, that is, to the SiN layer formed on the wafers 200.

Specifically, the valves 243e and 243g are opened to allow the third processing gas to flow through the gas supply pipes 232e and 232g. A flow rate of the third processing gas is regulated by the MFCs 241e and 241g, and supplied into the process chamber 201 via the nozzles 249b and 249a (supply of the third processing gas). At this time, RF power is applied from the RF power supply 320 to the electrodes 300. The third processing gas supplied into the process chamber 201 is excited to a plasma state in the interior of the process chamber 201, and is then supplied as an active species to the wafers 200 and exhausted from the exhaust pipe 231. Further, at this time, the valves 243b and 243c are closed to stop the supply of the inert gas into the process chamber 201. That is, in this step, the third processing gas alone is supplied into the process chamber 201 via the nozzles 249a and 249b, and the supply of any gas other than the third processing gas into the process chamber 201 is not performed. In addition, as in the case of step b, when a N₂ gas or a noble gas is used as the third processing gas in this step, no gas other than the gas used as the third processing gas is supplied into the process chamber 201 via the nozzles 249a and 249b.

Processing conditions in this step are exemplified as follows:
Processing pressure: 2 to 6 Pa, specifically 2.66 to 5.32 Pa, more specifically 3 to 4 Pa;
Supply flow rate of third processing gas (for each gas supply pipe): 0.01 to 2 slm; and
Supply time of third processing gas: 1 to 600 seconds, specifically 10 to 60 seconds. Other processing conditions are set to be the same as those in step b.

In the present embodiment, the flow rates of the third processing gas supplied from each of the nozzles 249a and 249b are the same. This facilitates a more uniform concentration distribution of the third processing gas inside the process chamber 201.

By exciting the third processing gas such as a H-containing gas to a plasma state and supplying it to the wafers 200 under the above-described condition, the SiN layer formed on the wafers 200 is modified. At this time, impurities such as Cl remaining in the SiN layer form a gaseous substance containing at least Cl in the process of a modification reaction of the SiN layer by an active species, and are discharged from the process chamber 201. Thus, the SiN layer modified in this step becomes a layer with fewer impurities such as Cl than the SiN layer formed in step b. Further, the SiN layer is densified due to this modification, and the SiN layer modified in this step is higher in density than the SiN layer formed in step b.

After the modification process of the SiN layer is completed, the valves 243e and 243g are closed to stop the supply of the third processing gas into the process chamber 201. Further, the supply of RF power to the electrodes 300 is stopped. Then, according to the same processing procedure as the purging in step a, the valves 243b and 243c are opened to allow an inert gas to be supplied into the process chamber 201 via the nozzles 249a and 249b, so that remaining gases and the like inside the process chamber 201 are removed from the process chamber 201 (purging).

A gas with a composition different from that of the second processing gas is used as the third processing gas. In addition, “with a different composition” may include, for example, a case in which the molecular structures or states of the same type of gases are different, or a case in which mixing ratios of a plurality of gases in a mixed gas of the gases are different.

As the third processing gas, for example, hydrogen-containing gases such as a H₂ gas, a H₂O gas, and a H₂O₂ gas, noble gases such as an Ar gas or a He gas, and a mixed gas containing a hydrogen-containing gas and a noble gas may be used. One or more of these may be used as the third processing gas. When a noble gas is used as the third processing gas, it acts as an activated gas by being excited to a plasma state.

### [Performing Cycle Predetermined Number of Times]

By performing a cycle a predetermined number of times (n times, n is an integer of 1 or more), the cycle including non-simultaneously, that is, without synchronization, performing the above-described steps a, b, and c, for example, a silicon nitride film (SiN film) of a predetermined thickness may be formed as a film of a predetermined thickness on the base, which is the surface of the wafers 200. The above-described cycle may be performed a plurality of times. That is, a thickness of the SiN layer formed per cycle may be set to be smaller than a desired film thickness, and the above-described cycle may be performed a plurality of times until the thickness of the SiN film formed by stacking SiN layers reaches the desired film thickness. In addition, when a N-, C-, and H-containing gas is used as a reactant gas, for example, a silicon carbonitride layer (SiCN layer) may also be formed in step b, and by performing the above-described cycle a predetermined number of times, for example, a silicon carbonitride film (SiCN film) may also be formed on the surface of the wafers 200.

### (After-Purge and Returning to Atmospheric Pressure)

After the process of forming a SiN film of a desired thickness on the wafers 200 is completed, an inert gas serving as a purge gas is supplied into the process chamber 201 from each of the nozzles 249a and 249b, and is exhausted from the exhaust port 231a. Thus, the interior of the process chamber 201 is purged, and any gases, reaction by-products and the like remaining in the process chamber 201 are removed from the process chamber 201 (after-purge). Thereafter, the internal atmosphere of the process chamber 201 is substituted with the inert gas (inert gas substitution), and the internal pressure of the process chamber 201 is returned to the atmospheric pressure (returning to atmospheric pressure).

### (Boat Unloading)

Thereafter, the seal cap 219 is moved down by the boat elevator 115 to open the lower end of the manifold 209. Then, the processed wafers 200 supported by the boat 217 is unloaded (boat unloading) from the lower end of the manifold 209 to the outside of the reaction tube 203. After the boat unloading, the lower end opening of the manifold 209 is sealed by the shutter 219s.

### (Wafer Cooling)

After the boat unloading, that is, after the shutter closing, the processed wafers 200 are cooled while being supported by the boat 217, until the wafers 200 reach a predetermined temperature at which the wafers 200 may be discharged (wafer cooling).

### (Wafer Discharging)

After the wafer cooling, the processed wafers 200 cooled to the predetermined temperature at which the wafers 200 may be discharged, is discharged from the boat 217 (wafer discharging).

In this way, a series of processes for forming a film on the wafers 200 are completed. These processes are performed a predetermined number of times (at least once).

### (3) Effects of the Embodiments

According to the embodiments of the present disclosure, one or more of the following effects may be achieved.

(a) In step b of plasma-exciting the second processing gas, the second processing gas is supplied from both of the nozzles 249a and 249b, and further, in step c of plasma-exciting the third processing gas, the third processing gas is supplied from both of the nozzles 249a and 249b. By not supplying any gas other than the processing gas from any of the nozzles suppressing deteriorations of in-plane uniformity of film quality, film thickness, and the like across the surface of the wafers 200 and inter-wafer uniformity, which may otherwise be caused by the plasma excitation of gases other than the processing gas is possible.

(b) In step a, by not plasma-exciting the first processing gas, suppressing excessive decomposition of the first processing gas due to plasma excitation is possible.

(c) In step a, by supplying the inert gas different from the first processing gas into the process chamber 201 from the nozzle 249b, preventing the backflow of the first processing gas into the nozzle 249b in step a is possible.

(d) Even if a N₂ gas is used as the inert gas in step a, the N₂ gas is not supplied into the process chamber 201 via the nozzles 249a and 249b in steps b and c. Therefore, avoiding the influence on substrate processing caused by the plasma excitation of the N₂ gas is possible.

(e) By not supplying any gas other than the second processing gas into the process chamber 201 in step b, and by not supplying any gas other than the third processing gas into the process chamber 201 in step c, suppressing the influence on substrate processing caused by the plasma excitation of gases other than the processing gas is possible.

(f) In steps b and c, by not supplying the inert gas into the process chamber 201, suppressing the influence on substrate processing caused by the plasma excitation of the inert gas other than the second processing gas and third processing gas is possible. Further, the influence on substrate processing caused by the inert gas supplied from the nozzles in step b and step c does not need to be considered and therefore, the inert gas used in step a may be appropriately and freely selected.

(g) By providing the plasma exciter (e.g., electrodes 300), configured to plasma-excite the gas inside the process chamber 201 at the outer periphery of the process chamber 201, it is easier to uniformly supply the plasma-excited processing gas to the wafers 200. In other words, it is easier to perform uniform processing on the wafers 200.

(h) The above-described various effects are obtained regardless of which of the above-described various first processing gases is used, which of the above-described various second processing gases is used, and which of the above-described various third processing gases is used.

### (4) Modifications

The configuration of the substrate processing apparatus in the present embodiment may be modified as in modifications described below. Unless otherwise stated, the configuration in each modification is the same as that in the above-described embodiments, and elements that are substantially the same as those described in FIG. 1 are given the same reference numerals, and the description thereof is omitted.

### (First Modification)

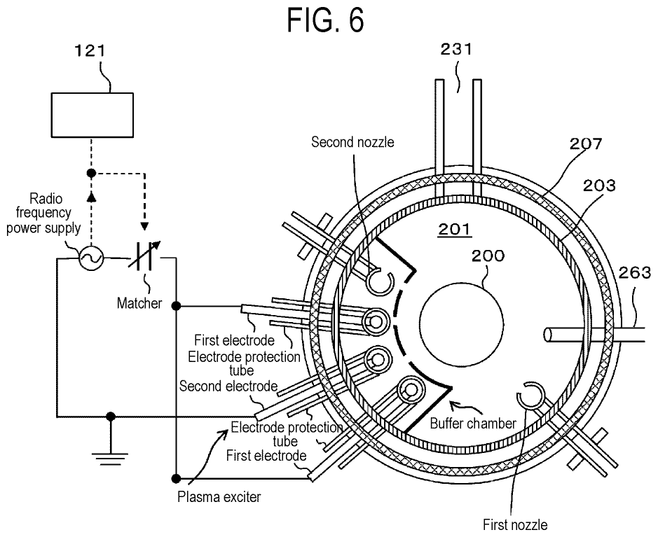

As illustrated in FIG. 6, the process chamber may further include a buffer chamber, and the second nozzle serving as the second supplier (second supply port) may be configured to supply a gas into the process chamber through the buffer chamber, whereas the first nozzle serving as the first supplier (first supply port) may be configured to supply a gas into the process chamber without passing through the buffer chamber. Furthermore, a plasma exciter including first and second electrodes and an electrode protective tube, which serves to plasma-excite a gas supplied into the buffer chamber, may be installed at the interior of the buffer chamber. In addition, the buffer chamber is not limited to being installed at the interior of the reaction tube 203 as illustrated in FIG. 6, and may instead be installed to extend (protrude) radially outward from the reaction tube 22u03.

Specifically, as illustrated in FIG. 6, in the buffer chamber, two rod-shaped first electrodes and one rod-shaped second electrode, which are made of conductors and are of elongated structures, are disposed along the direction (arrangement direction) in which the wafers 200 are stacked, from the lower side to the upper side of the reaction tube 203. Each of the first and second electrodes is installed parallel to the second nozzle. Each of the first and second electrodes is protected by being covered with the electrode protective tube from the upper side to the lower side. Among the first and second electrodes, two first electrodes disposed at both ends are connected to a radio frequency power supply via a matcher, while the second electrode is connected to a reference potential (ground) and is grounded. That is, the first electrodes connected to the radio frequency power supply and the grounded second electrode are disposed alternately, and the second electrode disposed between the two first electrodes connected to the radio frequency power supply is commonly used as a grounded electrode by the two first electrodes. In other words, the grounded second electrode is disposed to be sandwiched between the two adjacent first electrodes connected to the radio frequency power supply, forming a pair with each of the first electrodes to generate plasma. In addition, instead of being installed in the interior of the buffer chamber, a plurality of electrodes may be installed on the side surface of the buffer chamber, sandwiching the buffer chamber therebetween.

In the present modification, the same effects as those of the above-described embodiment are obtained as well. Further, in this modification, the second and third processing gases inside the buffer chamber may be efficiently plasma-excited in the above-described steps b and c.

Further, as described above, the plasma exciter is configured to include at least one first electrode to which radio frequency power is applied and at least one second electrode to which a reference potential is applied. In the plasma exciter configured in this manner, a plasma generation region may extend to a region outside the buffer chamber inside the process chamber. Therefore, for example, when a gas other than the second processing gas is supplied into the process chamber via the first nozzle in step b, this gas may be plasma-excited in the region outside the buffer chamber, which may potentially affect substrate processing. However, by also supplying the second processing gas via the first nozzle and not supplying any gas other than the second processing gas in step b, it is possible to suppress the influence on substrate processing caused by other gases that are plasma-excited in the region outside the buffer chamber, even when using the above-described plasma exciter in the present modification.

In the present modification, it is desirable that in the above-described steps b and c, the flow rates of the second and third processing gases supplied into the process chamber via the second nozzle are greater than the flow rates of the second and third processing gases supplied into the process chamber via the first nozzle. Thus, the flow rates of the second and third processing gases supplied into the buffer chamber, where the gases are efficiently plasma-excited, are increased, and the flow rates of the second and third processing gases supplied via the first nozzle to the outside of the buffer chamber are minimized, so as to reduce the amount of gas used.

### (Second Modification)

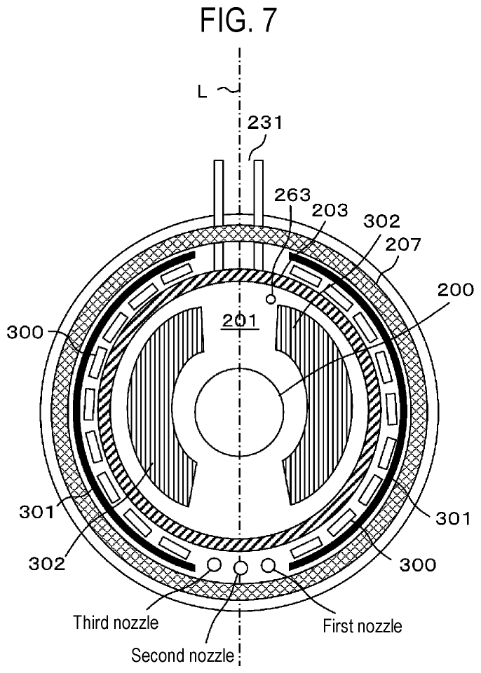

As illustrated in FIG. 7, in addition to the first and second nozzles, a third nozzle serving as a third supplier (third supply port) may be further installed inside the process chamber 201. In the above-described step a, the supply of the first processing gas into the process chamber 201 via the third nozzle is not performed, and in the above-described steps b and c, the second and third processing gases are respectively supplied into the process chamber 201 via the third nozzle.

In the present modification, the same effects as those of the above-described embodiments are obtained as well. In this modification, facilitating a more uniform concentration distribution of the second processing gas and/or the third processing gas inside the process chamber 201 is much easier.

In addition, in the present modification, an example in which three nozzles are installed inside the process chamber 201 is been described, but the number of nozzles is not limited thereto, and three or more nozzles may be installed. Even in an example in which three or more nozzles are installed, the same effects as those in this modification may be obtained by supplying the second and third processing gases into the process chamber 201 via each of the nozzles in the above-described steps b and c.

Further, as another modification, regardless of the number of nozzles installed inside the process chamber 201, in step a, the supply of the first processing gas into the process chamber 201 via nozzles configured to supply gases into the process chamber 201, including the second nozzle, except for the first nozzle (that is, suppliers other than the first nozzle) is not performed. In step b, the second processing gas is supplied into the process chamber 201 via the entirety of the nozzles, and in step c, the third processing gas is supplied into the process chamber 201 via the entirety of the nozzles. In the present modification, the same effects as those of the above-described embodiments are obtained as well.

### Other Embodiments of Present Disclosure

The embodiments of the present disclosure is specifically described above. However, the present disclosure is not limited to the above-described embodiments, and may be changed in various ways without departing from the gist of the present disclosure.

For example, as the second processing gas, in addition to the above-described N- and H-containing gas and N-, C- and H-containing gas, a carbon (C)-containing gas such as an ethylene (C₂H₄) gas, an acetylene (C₂H₂) gas or a propylene (C₃H₆) gas, a boron (B)-containing gas such as a diborane (B₂H₆) gas or a trichloroborane (BCl₃) gas, an oxygen (O₂) gas, an ozone (O₃) gas, a mixed gas of O₂ gas and H₂ gas, water vapor (H₂O gas), a hydrogen peroxide (H₂O₂) gas, a nitrous oxide (N₂O) gas, a nitric oxide (NO) gas, a nitrogen dioxide (NO₂) gas, a carbon monoxide (CO) gas, or a carbon dioxide (CO₂) gas may be used. In addition, in the case of supplying a mixed gas, two gases may be mixed (pre-mixed) inside a supply pipe and then be supplied into the process chamber 201. Alternatively, two gases may be separately supplied into the process chamber 201 from different supply pipes and may be mixed (post-mixed) inside the process chamber 201. One or more of these gases may be used as the second processing gas.

Further, similarly to the third processing gas, a H-containing gas, a noble gas, or a mixed gas containing a H-containing gas and a noble gas may be used as the second processing gas. However, the second and third processing gases are different from each other.

Further, the present disclosure may also be applied in the case in which, for example, a first processing gas containing a metal element such as aluminum (Al), titanium (Ti), hafnium (Hf), zirconium (Zr), tantalum (Ta), molybdenum (Mo), or tungsten (W) is used, and a nitride film containing a metal such as an aluminum nitride (AlN) film, a titanium nitride (TiN) film, a hafnium nitride (HfN) film, a zirconium nitride (ZrN) film, a tantalum nitride (TaN) film, a molybdenum nitride (MoN) film, a tungsten nitride (WN) film, an aluminum carbonitride (AlCN) film, a titanium carbonitride (TiCN) film, a hafnium carbonitride (HfCN) film, a zirconium carbonitride (ZrCN) film, a tantalum carbonitride (TaCN) film, a molybdenum carbonitride (MoCN) film, a tungsten carbonitride (WCN) film, a titanium aluminum nitride (TiAlN) film, or a titanium aluminum carbonitride (TiAlCN) film is formed on the wafers 200 by using the above-described processing sequence. Even in such a case, the same effects as those of the above-described embodiments are obtained.

Further, in the above-described embodiments, the case in which in step a, the inert gas is supplied into the process chamber 201 from both the nozzles 249a and 249b is described by way of example. However, the present disclosure is not limited thereto. For example, in step a, the inert gas may be supplied into the process chamber 201 from the nozzle 249b alone. Even in such a case, the same effects as those of the above-described embodiments are obtained as well.

In the above-described embodiments, the case in which the flow rates of the gases supplied from the nozzles 249a and 249b are the same in both steps b and c is described by way of example. However, the present disclosure is not limited thereto. For example, the flow rates of the gases supplied respectively from the nozzles 249a and 249b may be the same in either step b or step c. Further, the flow rates of the gases supplied respectively from the nozzles 249a and 249b may be different in at least one selected from the group of step b and step c. For example, the flow rate of the gas supplied from one nozzle may be set to be sufficiently smaller than the flow rate of the gas supplied from the other nozzle to a degree that can prevent the backflow of the gas into the nozzle. Even in such a case, the same effects as those of the above-described embodiments are obtained as well.

Further, the above-described first supplier, second supplier, and third supplier are not limited to tubular nozzles, and may each be configured by other gas supply mechanisms including openings for discharging gases.

Further, in addition to a CCP, for example, an inductively coupled plasma may be used as a plasma generation method. Even in such a case, the same effects as those of the above-described embodiments are obtained as well.

Recipes used in each process may be provided individually based on the processing contents and may be recorded in the memory 121c via a telecommunication line or the external memory 123. Further, at the beginning of each process, the CPU 121a may properly select an appropriate recipe from the recipes recorded in the memory 121c based on the processing contents.

In the above-described various embodiments and various modifications, examples in which a film is formed by using a batch-type substrate processing apparatus capable of processing a plurality of substrates at a time are described. The present disclosure is not limited to the above-described various embodiments and various modifications, but may be suitably applied, for example, to a case in which a film is formed by using a single wafer-type substrate processing apparatus configured to process a single substrate or several substrates at a time. Further, in the above-described various embodiments and various modifications, examples in which a film is formed by using a substrate processing apparatus including a hot-wall-type process furnace are described. The present disclosure is not limited to the above-described various embodiments and various modifications, but may also be suitably applied to a case in which a film is formed by using a substrate processing apparatus including a cold-wall-type process furnace.

Even in the case of using such substrate processing apparatuses, respective processes may be performed according to the same processing procedures and processing conditions as described in the above-described various embodiments and various modifications, and to the same effects as those of the above-described various embodiments and various modifications are obtained as well.

The above-described various embodiments and various modifications may be used in proper combinations. The processing procedures and processing conditions at used in this case may be the same as, for example, the processing procedures and processing conditions in the above-described various embodiments and various modifications.

According to the present disclosure, it is possible to suppress the influence on substrate processing caused by plasma excitation of gases other than a processing gas to be plasma-excited.

While certain embodiments are described above, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
(a) supplying a first processing gas from a first supplier into a process chamber in which the substrate is accommodated, while not supplying the first processing gas into the process chamber from a second supplier different from the first supplier;
(b) supplying a second processing gas into the process chamber from each of the first supplier and the second supplier, and plasma-exciting the second processing gas inside the process chamber; and
(c) supplying a third processing gas, which has a composition different from that of the second processing gas, into the process chamber from each of the first supplier and the second supplier, and plasma-exciting the third processing gas inside the process chamber.

2. The method of claim 1, wherein in (a), the first processing gas is not plasma-excited.

3. The method of claim 1, wherein in (a), an inert gas different from the first processing gas is supplied into the process chamber from the second supplier.

4. The method of claim 3, wherein in (b) and (c), the supply of the inert gas into the process chamber is stopped.

5. The method of claim 4, further comprising:
(d) purging the process chamber by supplying an inert gas into the process chamber from each of the first supplier and the second supplier, after at least one selected from the group of (b) and (c).

6. The method of claim 1, wherein in (b), no gas other than the second processing gas is supplied into the process chamber, and
wherein in (c), no gas other than the third processing gas is supplied into the process chamber.

7. The method of claim 1, wherein (a), (b), and (c) are performed non-simultaneously.

8. The method of claim 1, wherein the first processing gas is a precursor gas containing a predetermined element,
wherein the second processing gas is a nitriding gas, and
wherein the third processing gas is a hydrogen-containing gas, a noble gas, or a mixed gas containing the hydrogen-containing gas and the noble gas.

9. The method of claim 1, wherein a plasma exciter configured to plasma-excite a gas inside the process chamber is installed at an outer periphery of the process chamber.

10. The method of claim 9, wherein the plasma exciter is configured to plasma-excite both gases supplied from the first supplier and the second supplier.

11. The method of claim 9, wherein in at least one of (b) and (c), flow rates of gases supplied from the first supplier and the second supplier respectively are identical.

12. The method of claim 1, wherein the second supplier is configured to supply a gas into the process chamber through a buffer chamber, and
wherein the first supplier is configured to supply a gas into the process chamber without passing through the buffer chamber.

13. The method of claim 12, wherein a plasma exciter configured to plasma-excite a gas supplied into the buffer chamber is installed inside the buffer chamber.

14. The method of claim 13, wherein the plasma exciter includes a first electrode, to which radio frequency power is applied, and a second electrode to which a reference potential is applied.

15. The method of claim 12, wherein in (b), a flow rate of the second processing gas supplied into the process chamber from the second supplier is greater than a flow rate of the second processing gas supplied into the process chamber from the first supplier.

16. The method of claim 1, wherein in (a), the first processing gas is not supplied into the process chamber from a third supplier different from both the first supplier and the second supplier,
wherein in (b), the second processing gas is supplied into the process chamber from the third supplier, and
wherein in (c), the third processing gas is supplied into the process chamber from the third supplier.

17. The method of claim 1, wherein in (b), the second processing gas is supplied into the process chamber from an entirety of suppliers configured to supply a gas into the process chamber, including the first supplier and the second supplier, and
wherein in (c), the third processing gas is supplied into the process chamber from the entirety of suppliers.

18. A method of manufacturing a semiconductor device, comprising the method of claim 1.

19. A non-transitory computer-readable recording medium storing a program that causes, by a computer, a substrate processing apparatus to perform a process of processing a substrate, the process comprising:
(a) supplying a first processing gas from a first supplier into a process chamber in which the substrate is accommodated, while not supplying the first processing gas into the process chamber from a second supplier different from the first supplier;
(b) supplying a second processing gas into the process chamber from each of the first supplier and the second supplier, and plasma-exciting the second processing gas inside the process chamber; and
(c) supplying a third processing gas, which has a composition different from that of the second processing gas, into the process chamber from each of the first supplier and the second supplier, and plasma-exciting the third processing gas inside the process chamber.

20. A substrate processing apparatus comprising:
a process chamber configured to accommodate a substrate;
a first supplier and a second supplier each configured to supply a gas into the process chamber;
a plasma exciter configured to plasma-excite a gas inside the process chamber;
a gas supply system configured to supply a first processing gas, a second processing gas, and a third processing gas into the process chamber via at least one of the first supplier and the second supplier; and
a controller configured to be capable of controlling the plasma exciter and the gas supply system so as to perform a process including:
(a) supplying the first processing gas into the process chamber from the first supplier, while not supplying the first processing gas into the process chamber from the second supplier;
(b) supplying the second processing gas into the process chamber from each of the first supplier and the second supplier, and plasma-exciting the second processing gas inside the process chamber; and
(c) supplying the third processing gas into the process chamber from each of the first supplier and the second supplier, and plasma-exciting the third processing gas inside the process chamber.
